(19) United States
(12) Patent Application Publication
(10) Pub. No.: US 2025/0001619 A1
(43) Pub. Date: Jan. 2, 2025

(54) SUCTION DEVICE AND ROBOT

(71) Applicants: SHANGHAI FLEXIV ROBOTICS TECHNOLOGY CO., LTD., Shanghai (CN); FLEXIV LTD., Grand Cayman, Cayman Islands (GB)

(72) Inventors: Wenbin LI, Santa Clara, CA (US); Hao JIANG, Santa Clara, CA (US)

(21) Appl. No.: 18/253,863

(22) PCT Filed: Mar. 10, 2023
(86) PCT No.: PCT/CN2023/080724

§ 371 Date: May 22, 2023

(51) Int. Cl. B25J 15/06

(52) U.S. Cl. CPC B25J 15/0683

(57) ABSTRACT

A suction device includes a suction body including an inner surface that is in contact with an object to be sucked, and has an air hole in the middle thereof; a holder connected to the suction body, and having an air channel that being in communication with the air hole, the air channel being connected to a vacuum device; and a directional dry adhesive layer is provided on the inner surface of the suction body, and the directional dry adhesive layer having a plurality of micro-wedge structures inclined in a direction away from the air hole.

### TECHNICAL FIELD

The present disclosure relates to suction devices, in particular to a suction type suction device and a robot having the suction device.

### BACKGROUND

The conventional suction type device has the problems of weak shear load, torque load and moment resistance. Some suction devices are designed as non-slip suctions, which have a hard rubber material next to air holes in the suction. The problem with this solution is that the rubber material needs to be pressed hard on a surface of an object to create enough friction, and this pressure is determined by the required friction and the friction coefficient. The friction coefficient is usually less than one. This pressure depletes the suction force due to force balance. In addition, the use of additional adhesive can significantly increase the coefficient of friction or adhesion, so that only a low pressing force needs to be used to provide adsorption. However, most adhesives are difficult to separate from the object once applied and leave a residue on the surface that is difficult to clean.

### SUMMARY

Accordingly, it is necessary to provide a suction device with good suction force and no residue and a robot having the suction device.

A suction device includes:
a suction body, a middle of the suction body being provided with an air hole, an inner surface of the suction body being configured to be in contact with an object to be sucked;
a holder connected to the suction body, the holder having an air channel being in communication with the air hole, the air channel being configured to be connected to a vacuum device; and
a directional dry adhesive layer provided on the inner surface of the suction body, and the directional dry adhesive layer having a plurality of micro-wedge structures inclined in a direction away from the air hole.

The suction device provided by foregoing embodiment achieves stable loading and unloading of the micro-wedge structure of the directional dry adhesive layer through a deformation of the suction body due to the negative pressure, which increases a shear force and torque loading capacity of the suction device without substantially sacrificing a vacuum suction force along a suction direction, and does not leave any colloid residue on the surface of the object to be sucked.

In one of the embodiments, the suction body is made of deformable material, the holder includes a holder body and a support leg connected to the holder body, and the support leg surrounds the suction body, when the suction device is pressed against the object to be sucked and the suction body is in contact with the object to be sucked and is deformed, the support leg is configured to be in contact with the object to be sucked.

The suction device further includes an auxiliary support leg, a deformable diaphragm, and an auxiliary directional dry adhesive layer, the auxiliary support leg is located between the holder body and the auxiliary support leg, the auxiliary support leg is connected to the holder body through the deformable diaphragm, and the auxiliary directional dry adhesive layer is provided at a bottom of the auxiliary support leg.

In one of the embodiments, the deformable diaphragm comprises a plurality of deformable diaphragms, and the plurality of deformable diaphragms are spaced apart from each other between the auxiliary support leg and the holder body.

In one of the embodiments, the suction body is made of deformable material, the holder includes a holder body and a support leg connected to the holder body, and the suction body surrounds the support leg, when the suction device is pressed against the object to be sucked and the suction body is in contact with the object to be sucked and is deformed, the support leg is configured to be in contact with the object to be sucked.

In one of the embodiments, the suction device further includes an auxiliary support leg, a deformable diaphragm, and an auxiliary directional dry adhesive layer, the auxiliary support leg is located inside the support leg, the auxiliary support leg is connected to the holder body through the deformable diaphragm, and the auxiliary directional dry adhesive layer is provided at a bottom of the auxiliary support leg.

In one of the embodiments, the deformable diaphragm comprises a plurality of deformable diaphragms, and the plurality of deformable diaphragms are apart from each other between the auxiliary support leg and the support leg.

In one of the embodiments, the plurality of micro-wedge structures are distributed in a circular array, and each circle of the micro-wedge structures has a plurality of micro-wedge structures.

An end effector of a robot includes the suction device described in any one of the above.

A robot includes the end effector described in any one of the above.

### BRIEF DESCRIPTION OF THE DRAWINGS

In order to more clearly explain the embodiments of the present disclosure or the technical solutions in the related art, the accompanying drawings that need to be used in the description of the embodiments or the related art will be briefly described below. It is obvious that the drawings in the following description are only the embodiments of the present disclosure. For those skilled in the art, other drawings can be obtained according to the disclosed drawings without paying creative labor.

FIG. 1A is a schematic view of a suction device according to a first embodiment.

FIG. 1B is a schematic view of the suction device shown in FIG. 1A being fixed on an object to be sucked.

FIG. 1C is an enlarged view of part C in FIG. 1B.

FIG. 2A is a schematic view of the suction device according to a second embodiment.

FIG. 2B is a schematic view of the suction device shown in FIG. 2A being fixed on the object to be sucked.

FIG. 3A is a schematic view of the suction device according to a third embodiment.

FIG. 3B is a schematic view of the suction device shown in FIG. 3A being fixed on the object to be sucked.

FIG. 4A is a schematic view of the suction device according to a fourth embodiment.

FIG. 4B is a schematic view of the suction device shown in FIG. 4A being fixed on the object to be sucked.

FIG. 5A is a schematic view of the suction device according to a fifth embodiment.

FIG. 5B is a schematic view of the suction device shown in FIG. 5A being fixed on the object to be sucked.

FIG. 6 is a schematic view of a robot according to an embodiment.

### DETAILED DESCRIPTION OF THE EMBODIMENTS

In order to make the purposes, technical solutions and advantages of the embodiments of the present disclosure clearer, the technical solutions in the embodiments of the present disclosure will be clearly and completely described below in conjunction with the drawings in the embodiments of the present disclosure. Apparently, the described embodiments are some of the embodiments of the present disclosure, but not all of them. The components of the embodiments of the present disclosure generally described and illustrated in the figures herein may be arranged and designed in a variety of different configurations.

Accordingly, the following detailed description of the embodiments of the present disclosure provided in the accompanying drawings is not intended to limit the scope of the present disclosure, but merely represents selected embodiments of the present disclosure. Based on the embodiments in this present disclosure, all other embodiments obtained by persons of ordinary skill in the art without creative efforts fall within the protection scope of this present disclosure.

It should be noted that similar numerals and letters indicate similar items in the following figures, therefore, once an item is defined in one figure, it does not require further definition and explanation in subsequent figures.

In the description of the embodiments of the present disclosure, it should be understood that the orientations or positional relationships indicated by the terms “center”, “upper”, “lower”, “left”, “right”, “vertical”, “horizontal”, “inner”, “outer”, etc. are based on the orientations or positional relationships shown in the drawings, or the usual orientation or positional relationship of the product in use, or the orientation or positional relationship that is commonly understood by those skilled in the art, which is only for the convenience of describing the present disclosure and simplifying the description, but does not indicate or imply that the device or element referred to must have a specific orientation, be constructed and operated in a specific orientation, and thus should not be construed as limiting the present disclosure.

In addition, the terms “first”, “second”, etc. are only used for distinguishing descriptions, and should not be construed as indicating or implying relative importance.

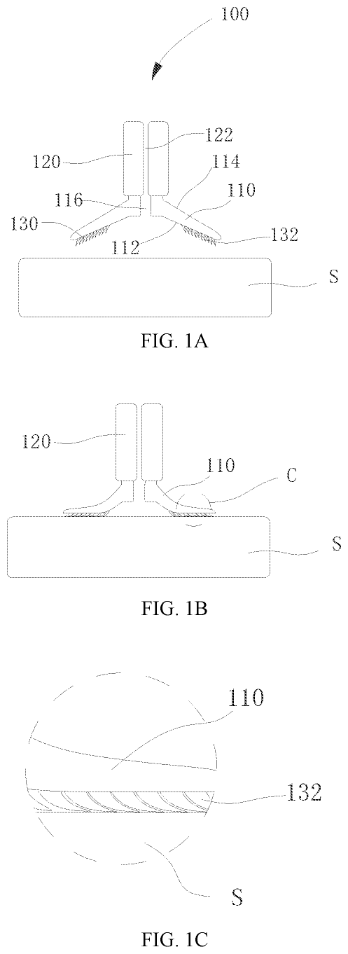

Referring to FIG. 1A and FIG. 1B, according to a first embodiment, a suction device 100 is provided, which is mainly configured to be detachably fixed on an object to be sucked (S). The suction device 100 includes a suction body 110 and a holder 120.

The suction body 110 is substantially bowl-shaped, and includes an inner surface 112 for contacting the object to be sucked (S) and an outer surface 114 opposite to the inner surface 112. The suction body 110 may be made of deformable material, e.g., rubber, silicone, etc. A middle of the suction body 110 is further provided with an air hole 116.

The holder 120 is fixedly connected to the middle portion of the suction body 110. An air channel 122 is provided inside the holder 120. One end of the air channel 122 is in communication with the air hole 116, and the other end thereof is connected to an external vacuum generating device (not shown) through a pipe, etc.

The suction device 100 further includes a directional dry adhesive layer 130 provided on the inner surface 112 of the suction body 110. As shown in FIG. 1C, the directional dry adhesive layer 130 has a plurality of micro-wedge structures 132 inclined in a direction away from the air hole 116.

In some embodiments, the plurality of micro-wedge structures 132 may be distributed in a circular array, and each circle of the micro-wedge structures 132 has a plurality of micro-wedge structures 132. Specifically, each micro-wedge structure 132 includes a first inclined surface and a second inclined surface, a bottom of the first inclined surface is connected to a bottom of the second inclined surface to form a protruding tip. An angle between the first inclined surface and a vertical plane is in a range of 50° to 80°, an angle between the second inclined surface and the vertical plane is in a range of 20° to 60°, and a height of the micro-wedge structure in a vertical direction is 40 μm to 200 μm. The micro-wedge structures 132 may be integrally molded with the suction body 110 through a mold, or may be formed separately, and then adhered on the inner surface 112 of the suction body 110 through glue, etc. In other embodiments, the plurality of micro-wedge structures 132 may be distributed in other forms, such as symmetrically distributed. A shape and a size of each micro-wedge structure 132 can also be adjusted according to actual needs.

Referring to FIG. 1B and FIG. 1C, in use, the suction device 100 can have two states: loading and unloading. After the suction body 110 is attached to a surface of the object to be sucked (S), an adhesion mechanism of the micro-wedge structure 132 is the van der Waals force effect. When no tangential load is loaded, the micro-wedge structure 132 is slightly inclined, and only the tips of the micro-wedge structure 132 are in contact with the surface of the object to be sucked (S). In this state, the van der Waals force is negligible, and the micro-wedge structure 132 is in a deactivated state. When the vacuum generating device is turned on, the air in the suction body 110 is extracted through the air hole 116 and the air channel 122, and the suction body 110 is elastically deformed due to the negative pressure, so that the micro-wedge structures 132 tightly press against the object to be sucked (S). The micro-wedge structures 132 are bent under force, and a contact area between the micro-wedge structures 132 and the object to be sucked (S) is significantly increased, thus generating normal adhesive force. At this time, the micro-wedge structure 132 is in an “open” state.

In the above embodiments, the directional dry adhesive layer 130 is provided on the inner surface 112 of the suction body 110. When the vacuum generating device is turned on, the suction body 110 is deformed and pushed onto the surface of the object to be sucked (S) due to an air pressure difference between the inner surface 112 and the outer surface 114, and the directional dry adhesive layer 130 is compressed and activated. Since an equivalent friction coefficient of the directional dry adhesive layer 130 exceeds that of a rubber material constituting the suction body 110, the shear force and torque resistance capabilities of the suction device 100 are enhanced. In addition, the suction body 110 shrinks evenly along a center thereof under the negative pressure, so as to provide the annular micro-wedge structure 132 with a load distributed along a center of a circle, thereby providing a stable and reliable load.

When the suction device 100 is no longer required to be fixed with the object to be sucked (S), the vacuum generating device can be turned off, and external air will enter an interior of the suction body 110 through the air hole 116 and the air channel 122, so that the air pressure difference between the inner surface 112 and the outer surface 114 of the suction body 110 becomes zero. The suction body 110 returns to an original undeformed state, so that the micro-wedge structure 132 of the directional dry adhesive layer 130 no longer presses against the surface of the object to be sucked (S), while only the tips are in contact with the object to be sucked (S), and the normal adhesion is negligible and the micro-wedge structure 132 is in the deactivated state. At this time, the suction device 100 can be removed from the surface of the object to be sucked (S) with a very low force without leaving any colloid residue on the surface of the object to be sucked (S).

The suction device 100 provided in the above embodiment achieves stable loading and unloading of the micro-wedge structure 132 of the directional dry adhesive layer 130 through a deformation of the suction body 110 due to the negative pressure, which increases the shear force and torque loading capacity of the suction device 100 without substantially sacrificing a vacuum suction force along a suction direction. Therefore, the suction device 100 can be used in manipulators to pick up porous objects or objects with irregular surfaces which cannot be achieved by the conventional vacuum suction manipulator, and effectively solve a shortcoming of the conventional vacuum suction manipulator such as low stability under the interference of adhesion and torque, which has wide application prospects in the picking and handling of ultra-thin wafers, ultra-thin glass, flexible circuit boards, wearable products and other products.

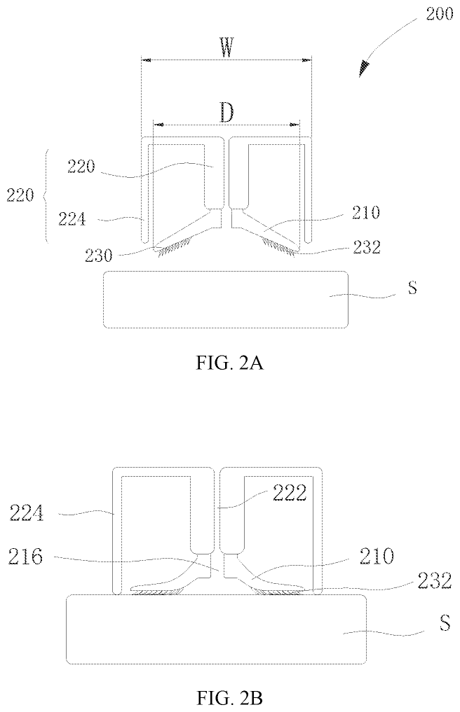

Referring to FIG. 2A and FIG. 2B, according to a second embodiment, a suction device 200 is provided, which is mainly configured to be detachably fixed on an object to be sucked (S). As similar to the first embodiment, the suction device 200 includes a suction body 210 and a holder 220. The difference between the suction device 200 of the second embodiment and the suction device 100 of the first embodiment is that the holder 220 includes a holder body 222 and a support leg 224 connected to the holder body 222. In this embodiment, the support leg 224 first extends laterally from the top of the holder body 222, and then is bent and extends toward the suction body 210. A width W of the support leg 224 is slightly greater than a diameter D of the suction body 210, so that the support leg 224 surrounds the suction body 210. In an embodiment, the holder body 222 and the support leg 224 may be made of a rigid material such as metal or engineering plastic.

A directional dry adhesive layer 230 is attached to an inner surface of the suction body 210. When the suction body 210 is just in contact with a surface of the object to be sucked (S), the support leg 224 is not in contact with the object to be sucked (S). When the vacuum generating device is turned on, the suction body 210 is deformed and pushed onto the surface of the object to be sucked (S) due to the air pressure difference between the inner surface and the outer surface thereof, and the directional dry adhesive layer 230 is compressed and activated. At this time, the suction body 210 deforms upwards so that the support leg 224 is in direct contact with the object to be sucked (S). Since the support leg 224 made of the rigid material surrounds the suction body 210, additional normal support can be provided to the suction body 210. Even if the object to be sucked (S) has a tendency to overturn relative to the suction device 200, the support leg 224 can resist overturning moments (the moment capability depends on the width W of the support leg 224 and a suction strength of the suction body 210) from all directions, so as to prevent the suction body 210 from swinging from left to right and from front to back, thus ensuring that the suction body 210 is kept in contact with the object to be sucked S at an angle and in a direction perpendicular to the surface of the object to be sucked S, further providing a stable and reliable loading load.

As similar to the first embodiment, when the suction device 200 is no longer required to be fixed with the object to be sucked (S), the vacuum generating device can be turned off, and external air will enter an interior of the suction body 210 through the air hole 216 and the air channel 222, so that an air pressure difference between the inner surface and the outer surface of the suction body 210 becomes zero. The suction body 210 returns to an original undeformed state, so that the micro-wedge structure 232 of the directional dry adhesive layer 230 no longer presses against the surface of the object to be sucked (S), while only the tips are in contact with the object to be sucked (S), and the normal adhesion is negligible and the micro-wedge structure 232 is in a deactivated state. At this time, the suction device 200 can be removed from the surface of the object to be sucked (S) with a very low force without leaving any colloid residue on the surface of the object to be sucked (S).

The suction device 200 provided in the above embodiment provides additional normal support for the suction body 210 through the support leg 224, so that the entire suction device 200 can resist large moment impact and improve a loading stability of the load.

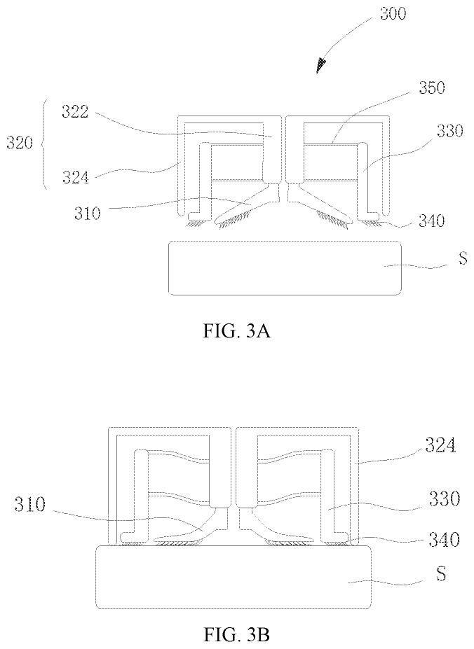

Referring to FIG. 3A to FIG. 3B, according to a third embodiment, a suction device 300 is provided, which is mainly configured to be detachably fixed on the object to be sucked (S). As similar to the second embodiment, the suction device 300 includes a suction body 310 and a holder 320, and the holder 320 includes a holder body 322 and a support leg 324 connected to the holder body 322. The difference between the suction device 300 and the suction device 200 is that the suction device 300 further includes an auxiliary support leg 330, an auxiliary directional dry adhesive layer 340, and a deformable diaphragm 350.

The auxiliary support leg 330 is located between the holder body 322 and the support leg 330, and surrounds the suction body 310. The auxiliary directional dry adhesive layer 340 is provided on a bottom of the auxiliary support leg 330. The auxiliary directional dry adhesive layer 340 may be made of the same material as that of the directional dry adhesive layer. The deformable diaphragm 350 is located between the holder body 322 and the auxiliary support leg 330, in other words, the auxiliary support leg 330 is connected to the holder body 322 through the deformable diaphragm 350. The deformable diaphragm 350 can be made of thin metal, plastic, rubber, etc. In this embodiment, two deformable diaphragms 350 are provided, and the two deformable diaphragms 350 are spaced apart from each other in a vertical direction between the auxiliary support leg 330 and the holder body 322. Specifically, one of the deformable diaphragms 350 is provided between a top of the auxiliary support leg 330 and a middle of the holder body 322, and the other deformable diaphragm 350 is provided between a middle of the auxiliary support leg 330 and a bottom of the holder body 322. In some embodiments, one, three or more deformable diaphragms 350 may be provided.

As similar to the second embodiment, when the suction body 310 is attached to the surface of the object to be sucked (S), the support leg 324 and the auxiliary support leg 330 are not in contact with the object to be sucked (S). When the vacuum generating device is turned on, the suction body 310 is deformed and pushed onto the surface of the object to be sucked (S) due to an air pressure difference between the inner surface and the outer surface thereof, and the directional dry adhesive layer is compressed and activated. At this time, the suction body 310 is deformed upwards, so that the support leg 324 are in direct contact with the object to be sucked (S). In addition, the two deformable diaphragms 350 may be deformed simultaneously, so that the auxiliary support leg 330 are also in direct contact with the object to be sucked (S) at the same time, and the auxiliary directional dry adhesive layer 340 located at the bottom of the auxiliary support leg 330 is compressed and activated.

As similar to the second embodiment, when the suction device 300 is no longer required to be fixed with the object to be sucked (S), the vacuum generating device can be turned off. The suction body 310 returns to an original undeformed state, so that the micro-wedge structure 332 of the directional dry adhesive layer no longer presses against the surface of the object to be sucked (S) and is in a deactivated state. At this time, the two deformable diaphragms 350 also return to an original undeformed state, so that the auxiliary directional dry adhesive layer 340 no longer presses against the surface of the object to be sucked (S) and is in a deactivated state. The suction device 300 can be removed from the surface of the object to be sucked (S) with a very low force without leaving any colloid residue on the surface of the object to be sucked (S).

In the suction device 300 provided by the third embodiments, the directional dry adhesive layer requires a minimum pressure to be activated before a high shear force can be provided. Therefore, when the vacuum generating device is turned on, the deformable diaphragm 350 will be deformed, so that the auxiliary directional dry adhesive layer 340 will be pressed very gently on the surface of the object to be sucked (S) and will be activated. When subjected to external shear force, the directional dry adhesive layer and the auxiliary directional dry adhesive layer 340 will jointly resist the shear force, and the deformable diaphragm 350 will also firmly fix the auxiliary support leg 330 on the surface of the object to be sucked (S), which improves the loading stability of the load.

In another embodiment, the suction body 310 and the directional dry adhesive layer on its inner surface may also be removed. In this case, the auxiliary directional dry adhesive layer 340 and the deformable diaphragm 350 are combined to form a structure similar to the suction body, which can provide sufficient suction force. The support leg 324 provides additional normal support for the auxiliary directional dry adhesive layer 340 and deformable diaphragm 350.

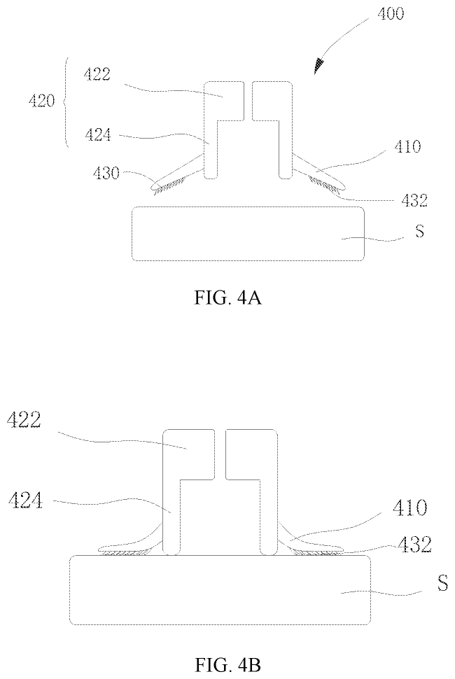

Referring to FIG. 4A and FIG. 4B, according to a fourth embodiment, a suction device 400 is provided, which is mainly configured to be detachably fixed on the object to be sucked (S). As similar to the first embodiment, the suction device 400 includes a suction body 410 and a holder 420. The difference between the suction device 400 and the suction device 100 is that the holder 420 includes a holder body 422 and a support leg 424 connected to the holder body 422. In this embodiment, the support leg 424 extends downward from a bottom of the holder body 222. The suction body 410 is provided around the support leg 424, that is, a width of the support leg 424 is less than a diameter of the suction body 410.

As similar to the second embodiment, when the suction body 410 is attached to the surface of the object to be sucked (S), the support leg 424 are not in contact with the object to be sucked (S). When the vacuum generating device is turned on, the suction body 410 is deformed and pushed onto the surface of the object to be sucked (S) due to the air pressure difference between the inner surface and the outer surface, and a micro-wedge structure 432 of the directional dry adhesive layer 430 is compressed and activated. At this time, the suction body 410 deforms upwards so that the support leg 424 is in direct contact with the object to be sucked (S). The support leg 224 made of rigid material can provide additional normal support for the suction body 410, which prevents the suction body 410 from swinging from left to right and from front to back, thus ensuring that the suction body 410 is kept in contact with the object to be sucked S at an angle and in a direction perpendicular to the surface of the object to be sucked (S), further providing a stable and reliable loading load.

When the suction device 400 is no longer required to be fixed to the object to be sucked (S), the vacuum generating device can be turned off, and the external air will enter an interior of the suction body 410 through the air hole 416 and the air channel 422, so that an air pressure difference between the inner surface and the outer surface of the suction body 410 becomes zero. The suction body 410 returns to an initial undeformed state, so that the micro-wedge structure 432 of the directional dry adhesive layer 430 no longer presses against the surface of the object to be sucked (S), while only the tips are in contact with the object to be sucked (S), and the normal adhesion is negligible and the micro-wedge structure 432 is in a deactivated state. At this time, the suction device 400 can be removed from the surface of the object to be sucked (S) with a very low force without leaving any colloid residue on the surface of the object to be sucked (S).

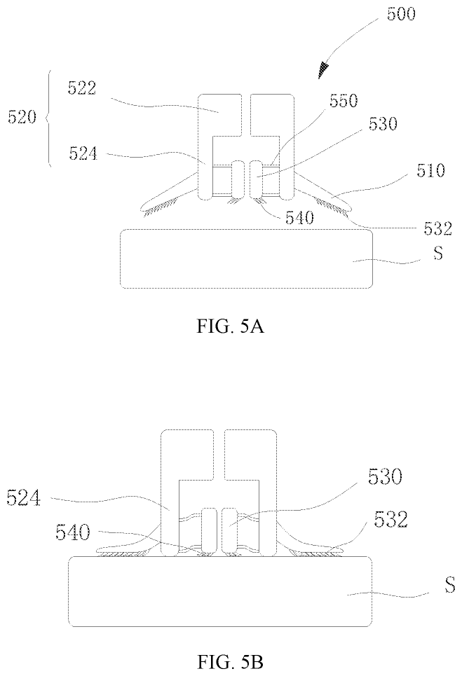

Referring to FIG. 5A and FIG. 5B, according to a fifth embodiment, a suction device 500 is provided, which is mainly configured to be detachably fixed on the object to be sucked (S). Similar to the fourth embodiment, the suction device 500 includes a suction body 510 and a holder 520, and the holder 520 includes a holder body 522 and a support leg 524 connected to the holder body 522. The difference between the suction device 500 and the suction device 400 is that the suction device 500 further includes an auxiliary support leg 530, an auxiliary directional dry adhesive layer 540, and a deformable diaphragm 550.

The auxiliary support leg 530 is located inside the support leg 524. The auxiliary directional dry adhesive layer 540 is provided at a bottom of the auxiliary support leg 530. The deformable diaphragm 550 is located between the support leg 524 and the auxiliary support leg 530, in other words, the auxiliary support leg 550 is connected to the support leg 524 through the deformable diaphragm 540. In this embodiment, two deformable diaphragms 550 are provided, and the two deformable diaphragms 550 are spaced apart from each other in a vertical direction between the auxiliary support leg 530 and the support leg 524. Specifically, one of the deformable diaphragms 550 is provided between a top of the auxiliary support leg 530 and a middle of the support leg 524, and the other deformable diaphragm 550 is provided between a bottom of the auxiliary support leg 530 and a bottom of the support leg 524. In some embodiments, one, three or more deformable diaphragms 550 may be provided.

As similar to the third embodiment, when the suction body 510 is attached to the surface of the object to be sucked (S), the support leg 524 and the auxiliary support leg 530 are not in contact with the object to be sucked (S). When the vacuum generating device is turned on, the suction body 510 is deformed and pushed onto the surface of the object to be sucked (S) due to an air pressure difference between the inner surface and the outer surface thereof, and the directional dry adhesive layer is compressed and activated. At this time, the suction body 510 is deformed upwards so that the support leg 524 are in direct contact with the object to be sucked (S). In addition, the two deformable diaphragms 550 may be deformed simultaneously, so that the auxiliary support leg 530 are also in direct contact with the object to be sucked (S) at the same time, and the auxiliary directional dry adhesive layer 540 located at the bottom of the auxiliary support leg 530 is compressed and activated.

When the suction device 500 is no longer required to be fixed with the object to be sucked (S), the vacuum generating device can be turned off. The suction body 510 returns to an original undeformed state, so that the micro-wedge structure 532 of the directional dry adhesive layer no longer presses against the surface of the object to be sucked (S) and is in a deactivated state. At this time, the two deformable diaphragms 550 also return to an original undeformed state, so that the auxiliary directional dry adhesive layer 540 no longer presses against the surface of the object to be sucked (S) and is in a deactivated state. At this time, the suction device 500 can be removed from the surface of the object to be sucked (S) with a very low force without leaving any colloid residue on the surface of the object to be sucked (S).

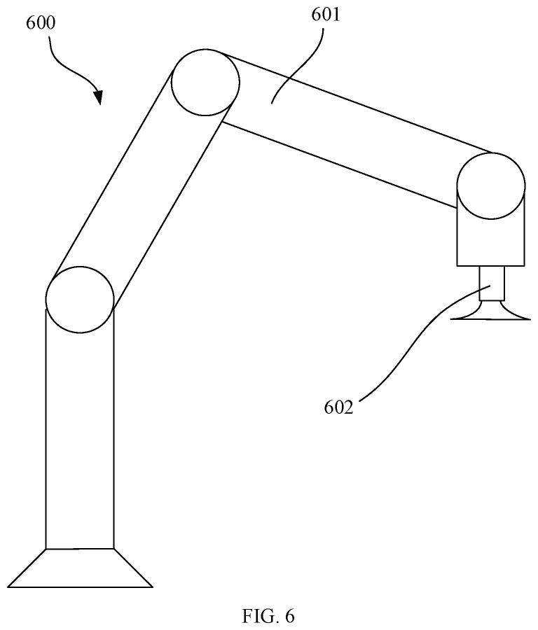

Referring to FIG. 6, according to an embodiment, a robot 600 is also provided. The robot 600 configured to grasp or release objects may include a plurality of articulation members 601 and an end effector 602. Specifically, the end effector 602 includes any of the suction devices illustrated in the previous embodiments. Those skilled in the art should understand that the structure shown in FIG. 6 is only an exemplary embodiment of the robot 600. In other embodiments, the robot 600 may include more components or fewer components, such as I/O devices, network access devices, communication buses, processors, memory, actuators and sensors, etc. For example, the robot 600 may include a processor and memory storing instructions that, when executed by the processor, cause the processor to implement a control system. The memory may also store instructions that, when executed by the processor, cause the processor to activate or deactivate the end effector 602 in order to grasp or release the object to be sucked.

The above-mentioned embodiments do not constitute a limitation on the protection scope of the technical solution. Any modifications, equivalent replacements and improvements made within the spirit and principles of the above-mentioned embodiments shall be included within the protection scope of this technical solution.

The foregoing descriptions are merely specific embodiments of the present invention, but are not intended to limit the protection scope of the present invention. Any variation or replacement readily figured out by a person skilled in the art within the technical scope disclosed in the present invention shall all fall within the protection scope of the present invention.

What is claimed is:

1. A suction device, comprising:
a suction body, a middle of the suction body being provided with an air hole, an inner surface of the suction body being configured to be in contact with an object to be sucked;
a holder connected to the suction body, the holder having an air channel in communication with the air hole, the air channel being configured to be connected to a vacuum device; and
a directional dry adhesive layer provided on the inner surface of the suction body, and the directional dry adhesive layer having a plurality of micro-wedge structures inclined in a direction away from the air hole.

2. The suction device according to claim 1, wherein the suction body is made of deformable material;
the holder comprises a holder body and a support leg connected to the holder body, and the support leg surrounds the suction body;
when the suction device is pressed against the object to be sucked and the suction body is in contact with the object to be sucked and deformed, the support leg is configured to be in contact with the object to be sucked.

3. The suction device according to claim 2, further comprising an auxiliary support leg, a deformable diaphragm, and an auxiliary directional dry adhesive layer, wherein the auxiliary support leg is located between the holder body and the auxiliary support leg, the auxiliary support leg is connected to the holder body through the deformable diaphragm, and the auxiliary directional dry adhesive layer is provided at a bottom of the auxiliary support leg.

4. The suction device according to claim 3, wherein the deformable diaphragm comprises a plurality of deformable diaphragms, and the plurality of deformable diaphragms are spaced apart from each other between the auxiliary support leg and the holder body.

5. The suction device according to claim 1, wherein the suction body is made of deformable material;
the holder comprises a holder body and a support leg connected to the holder body, and the suction body surrounds the support leg;
when the suction device is pressed against the object to be sucked and the suction body is in contact with the object to be sucked and deformed, the support leg is configured to be in contact with the object to be sucked.

6. The suction device according to claim 5, further comprising an auxiliary support leg, a deformable diaphragm, and an auxiliary directional dry adhesive layer, wherein the auxiliary support leg is located inside the support leg, the auxiliary support leg is connected to the holder body through the deformable diaphragm, and the auxiliary directional dry adhesive layer is provided at a bottom of the auxiliary support leg.

7. The suction device according to claim 6, wherein the deformable diaphragm comprises a plurality of deformable diaphragms, and the plurality of deformable diaphragms are spaced apart from each other between the auxiliary support leg and the support leg.

8. The suction device according to claim 1, wherein the plurality of micro-wedge structures are distributed in a circular array, and each circle of the micro-wedge structures has a plurality of micro-wedge structures.

9. An end effector of a robot, comprising the suction device according to claim 1.

10. A robot, comprising the end effector according to claim 9.
